(19) United States
(12) Patent Application Publication
(10) Pub. No.: US 2008/0163924 A1
(43) Pub. Date: Jul. 10, 2008

(54) Multijunction solar cell

(76) Inventor: Elisheva Sprung, Beitar Illit (IL)

Correspondence Address: Borealis Technical Limited, 23545 NW Skyline Blvd, North Plains, OR, 97133-9204, US

(21) Appl. No.: 12/006,742

(22) Filed: Jan. 4, 2008

(30) Foreign Application Priority Data
Jan. 4, 2007 (GB) GB0700071.4

(51) Int. Cl. H01L 31/042

(52) U.S. Cl. 136/249

(57) ABSTRACT

A multi-junction, monolithic, photovoltaic solar cell device is provided for converting solar radiation to photocurrent and photo voltage with improved efficiency. The solar cell comprises a plurality of semiconductor sub-cells, i.e., active p/n junctions, connected in series via tunnel junctions. To increase efficiency, each semiconductor cell is fabricated from the same semiconductor material so that all cells have the identical lattice constant. Nanosized indentations or protrusions are formed on the surface of each sub-cell, thereby modifying the size of the semiconductor bandgap and creating appropriate bandgaps to efficiently harness a larger portion of the solar spectrum. To further increase efficiency, the thickness of each sub-cell is controlled to match the photocurrent generated in each sub-cell.

### CROSS-REFERENCE TO RELATED APPLICATIONS

This application claims the benefit of U.K. Patent Application No. GB0700071.4, filed Jan. 4, 2007. The above-mentioned document is incorporated herein by reference in its entirety.

### BACKGROUND OF THE INVENTION

This invention relates to multifunction solar cells.

In U.S. Pat. No. 6,680,214 and U.S. Pat. App. No. 2004/0206881 methods are disclosed for the induction of a suitable bandgap and electron emissive properties into a substance, in which the substrate is provided with a surface structure corresponding to the interference of electron waves.

The space distribution of the probability wave associated with an elementary particle is given by:

ψ=Aexp(ikr) (1)

where k is the wave number and r is a vector connecting initial and final locations of the particle. FIG. 1 shows incident wave 101 Aexp(ikx) moving from left to right perpendicular to a surface dividing two domains. The surface is associated with a potential barrier.

Incident wave 101 Aexp(ikx) will mainly reflect back as reflected wave 103 βAexp(−ikx), and only a small part leaks through the surface to give transmitted wave 102 α(x)Aexp(ikx) (β≈1>>α). This is known as quantum mechanical tunneling. The elementary particle will pass the potential energy barrier with a low probability, depending on the potential energy barrier height.

In U.S. Pat. Nos. 6,531,703, 6,495,843 and 6,281,514, Tavkhelidze teaches a method for promoting the passage of elementary particles at or through a potential barrier comprising providing a potential barrier having a geometrical shape for causing de Broglie interference between said elementary particles.

Referring to FIG. 2, two domains are separated by a surface 201 having an indented shape, with height a. An incident probability wave 202 is reflected from surface 201 to give two reflected waves. Wave 203 is reflected from top of the indent and wave 204 is reflected from the bottom of the indent.

For certain values of a, the reflected probability wave equals zero meaning that the particle will not reflect back from surface 201. Leakage of the probability wave through the barrier will occur with increased probability.

Indents on the surface should have dimensions comparable to the de Broglie wavelength of an electron in order for this effect to be seen. Indents of these dimensions may be constructed on a surface by a number of means known in the art such as micro-machining. Alternatively, the indented shape may be introduced by depositing a series of islands on the surface.

For metals, this approach has a two-fold benefit. In the case that the potential barrier does not allow tunneling, providing indents on a surface of a metal creates for that metal an energy bandgap due to de Broglie wave interference inside the metal. In the case that the potential barrier is of such a type that an electron can tunnel through it, providing indents on a metal surface decreases the effective potential barrier between metal and vacuum (the work function). In addition, an electron moving from vacuum into an anode electrode having an indented surface will also experience de Broglie interference, which will promote the movement of said electron into said electrode, thereby increasing the performance of the anode.

WO03083177 teaches that a metal surface can be modified with patterned indents to increase the Fermi energy level inside the metal, leading to decrease in electron work function. This effect would exist in any quantum system comprising fermions inside a potential energy box. This approach can also be applied to semiconductors, in which case providing indents on the surface of a semiconductor modifies the size of the already present bandgap. This approach has many applications, including applications usually reserved for quantum dots.

In U.S. Pat. No. 6,117,344 methods for fabricating nano-structured surfaces having geometries in which the passage of elementary particles through a potential barrier is enhanced are described. The methods use combinations of electron beam lithography, lift-off, and rolling, imprinting or stamping processes.

WO9964642 discloses a method for fabricating nanostructures directly in a material film, preferably a metal film, deposited on a substrate. In a preferred embodiment a mold or stamp having a surface which is the topological opposite of the nanostructure to be created is pressed into a heated metal coated on a substrate. The film is cooled and the mold is removed. In another embodiment, the thin layer of metal remaining attached to the substrate is removed using bombardment with a charged particle beam.

Recent technology discloses an improved efficiency thin film solar cell wherein nanoscale indentations or protrusions are formed on the cross sectional surface of a carrier layer, onto which a thin metal film is deposited. The nanostructure underlying the metal film serves to reduce the work function of the metal and thereby assists in the absorption of holes created by solar photons. This leads to more efficient electricity generation in the solar cell.

Solar energy is an important source of energy. Photovoltaic devices fabricated from layers of semiconductor materials, commonly called solar cells, are presently used to convert solar energy directly into electricity for many electrically powered applications. However, greater solar energy to electrical energy conversion efficiencies are still needed in solar cells to bring the cost per watt of electricity produced into line with the cost of generating electricity with fossil fuels and nuclear energy and to lower the cost of telecommunication satellites.

Solar energy comprises electromagnetic radiation in a whole spectrum of wavelengths, i.e., discrete particles or photons at various energy levels, ranging from higher energy ultraviolet with wavelengths less than 390 nm to lower energy near-infrared with wavelengths as long as 3000 nm.

Because a semiconductor layer of a solar cell absorbs photons with energy greater than the bandgap of the semiconductor layer, a low bandgap semiconductor layer absorbs most of the photons in the received solar energy. However, useful electrical power produced by the solar cell is the product of the voltage and the current produced by the solar cell during conversion of the solar energy to electrical energy. Although a solar cell made from a low bandgap material may generate a relatively large current, the voltage is often undesirably low for many implementations of solar cells.

To achieve the goal of using most of the photons in the solar spectrum while simultaneously achieving higher output voltage, multi-junction solar cells have been developed. Multi-junction solar cells generally include multiple, differently-configured semiconductor layers with two or more solar energy conversion junctions, each of which is designed to convert a different solar energy or wavelength band to electricity. Thus, solar energy in a wavelength band that is not absorbed and converted to electrical energy at one semiconductor junction may be captured and converted to electrical energy at another semiconductor junction in the solar cell that is designed for that particular wavelength range or energy band.

FIG. 3 illustrates the basic structure of a prior art two junction solar cell. Shown is solar cell 300 which includes window layer 301, first cell 303 with junction 305 and second cell 307 with junction 309. Tunnel junction 311 separates first cell 303 from second cell 307. Substrate 313 lies at the base of solar cell 300. Electrical connectors 315 contact the two outermost layers of solar cell 300 and are connected to electrical device 317 which is powered by the electricity generated by solar cell 300.

As solar radiation enters solar cell 300 via window layer 301, first cell 303 and second cell 307 each absorb a portion of the solar radiation and convert the energy in the form of photons of the solar radiation to useable electric energy. To accomplish this conversion, first cell 303 and second cell 307 comprise layers of materials 302, 304 and 306, 308, respectively, that are doped (e.g., impurities are added that accept or donate electrons) to form n-type and p-type semiconductors. In this manner, the p/n or n/p junctions 305, 309 are formed in each of the first and second cells 303, 307, respectively.

Photons in the received sunlight having energy greater than the designed bandgap of first cell 303 will be absorbed and converted to electricity across semiconductor junction 305 or may pass through active first cell 303 to second cell 307 via tunnel junction 311. Photons with energy less than the designed bandgap of first cell 303 will pass through first cell 303 to second cell 307. Such lower energy sun light may be absorbed and converted to electricity across junction 309. To improve efficient conversion of a fuller range of the solar spectrum to electricity it is preferable that second cell 307 has a bandgap that differs significantly from the bandgap of first cell 303, thereby enabling incremental or stepwise absorption of photons of varying energy levels or wavelengths.

In this regard, illustrated prior art solar cell 300 is configured to absorb light in two incremental steps. In first cell 303, photons with energy above about 1.75 eV are absorbed, and photons of energy between about 1.1 eV and 1.75 eV are absorbed in second cell 307. As shown, cells 303 and 307 are supported by substrate 313.

Several difficulties have arisen in producing such multi-junction solar cells which has limited their energy conversion efficiency. First, it has proven difficult to fabricate each semiconductor junction so as to maintain high photovoltaic device quality and simultaneously the appropriate band structure, electron energy levels, conduction, and absorption, that provide the photovoltaic effect within the solar cell as the multiple layers of different semiconductor materials are deposited to form the solar cells. It is well known that photovoltaic quality may be improved in monolithic solar cells by lattice matching adjacent layers of semiconductor materials in the solar cell, meaning that each crystalline semiconductor material that is deposited and grown to form the solar cell has similar crystal lattice constants or parameters. Mismatching at the semiconductor junctions in the solar cells creates defects or dislocations in the crystal lattice of the solar cell, which causes degradation of critical photovoltaic quality characteristics, such as open-circuit voltage, short-circuit current, and fill factor.

Second, the energy conversion efficiency, including photocurrent and photo voltage, has proven difficult to maximize in multi-junction solar cells. Photocurrent flow can be improved if each solar cell junction of the semiconductor device can be current matched, in other words, to design each solar cell junction in the multi-junction device in a manner such that the electric current produced by each cell junction in the device is the same.

Current matching is important when a multi-junction solar cell device is fabricated with the individual semiconductor cells in the device connected in series, because, in a series circuit, current flow is limited to the smallest current produced by any one of the individual cells in the device. Current matching can be controlled during fabrication by selecting and controlling the relative bandgap energy absorption capabilities of the various semiconductor materials used to form the cell junctions and the thicknesses of each semiconductor cell in the multi-junction device.

In contrast, the photo voltages produced by each semiconductor cell are additive, and preferably each semiconductor cell within a multi-cell solar cell is selected to provide small increments of power absorption (e.g., a series of gradually reducing bandgap energies) to improve the total power, and specifically the voltage, output of the solar cell.

To address the above fabrication problems, a large number of materials and material compounds have been utilized in fabricating multi-junction, monolithic solar cell devices. However, these prior art solar cells have often resulted in lattice-mismatching, which may lead to photovoltaic quality degradation and reduced efficiency even for slight mismatching, such as less than one percent. Furthermore, even when lattice-matching is achieved, these prior art solar cells often fail to obtain desired photo voltage outputs. This low efficiency is caused, at least in part, by the difficulty of lattice-matching each semiconductor cell to commonly used and preferred materials for the substrate, such as germanium (Ge) or gallium-arsenide (GaAs) substrates.

As discussed above, it is preferable that each sequential junction absorb energy with a slightly smaller bandgap to more efficiently convert the full spectrum of solar energy. In this regard, solar cells are stacked in descending order of bandgap energy. However, the limited selection of known semiconductor materials, and corresponding bandgaps, that have the same lattice constant as the above preferred substrate materials has continued to make it difficult to design and fabricate a multi-junction, monolithic solar cell that efficiently converts the received solar radiation to electricity.

Current research is focused on producing or identifying materials with bandgaps of 1 eV and 1.25 eV for use as the bottom and intermediate layers respectively in multijunction solar cells.

### BRIEF SUMMARY OF THE INVENTION

From the foregoing, it may be appreciated that a need has arisen for a solar cell comprising semiconductor materials with desirable bandgap ranges, lattice constants substantially equivalent throughout the cell and with precisely matched currents so as to improve power output and solar energy conversion efficiency of solar cells. The present invention discloses an improved efficiency multi-junction solar cell. Each semiconductor sub-cell within the multi-junction solar cell is manufactured from the same semiconductor material so that all the sub-cells are exactly lattice matched. Different sized bandgaps are engineered in each sub-cell via the introduction of nanosized indentations or protrusions on the surface of the sub-cell. Cell thickness is varied in order to achieve precise current matching.

An advantage of the present invention is that since all the sub-cells within the multi-junction solar cell comprise the same semiconductor, lattice matching both between the sub-cells and the cell substrate is exact. This prevents energy losses due to imperfect lattice matching, wherein recombination occurs at defect sites leading to thermal energy losses.

A further advantage of the present invention is that the solar cell is grown monolithically in a single deposition process, rather than individual cells having to be formed and then stacked. Monolithic growth is an efficient process which avoids the manufacturing and technical difficulties associated with stacking.

Yet a further advantage of the present invention is that the photocurrents generated by each sub-cell are precisely matched by varying cell thicknesses, thereby harnessing all current produced.

A further advantage of the present invention is that the bandgap of the semiconductor materials is optimized in order to allow each sub-cell to absorb the desired part of the solar spectrum.

A further advantage of the present invention is that a larger portion of the solar spectrum is absorbed due to the presence of multiple sub-cells, each with a different bandgap, in the composite solar cell. This increases the efficiency of the cell, thereby reducing the cost of solar energy and so making it a more competitive energy source.

Still further advantages will become apparent from a consideration of the ensuing description and drawings.

### BRIEF DESCRIPTION OF THE SEVERAL VIEWS OF THE DRAWING

Embodiments of the present invention will now be described with reference to appropriate figures, which are given by way of example only and are not intended to limit the present invention.

For a more complete explanation of the present invention and the technical advantages thereof, reference is now made to the following description and the accompanying drawings in which:

FIG. 1 illustrates an incident probability wave, reflected probability wave and transmitted probability wave;

FIG. 2 illustrates an incident probability wave, two reflected probability waves and a transmitted probability wave interacting with a surface having a series of indents or protrusions;

FIG. 3 shows, in diagrammatic form, the structure of a prior art multi-junction solar cell; and

FIG. 4 shows a cross sectional view of the multi-junction solar cell of the present invention.

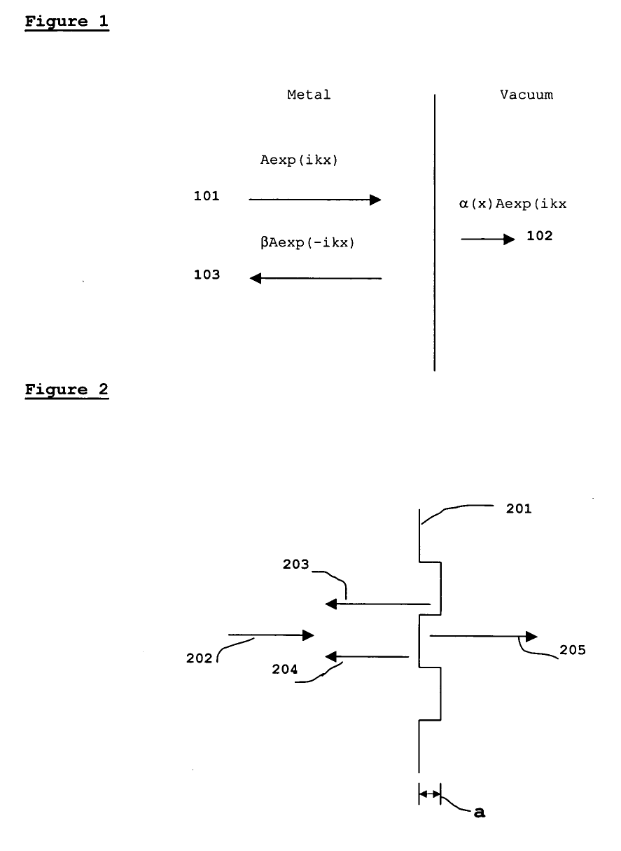

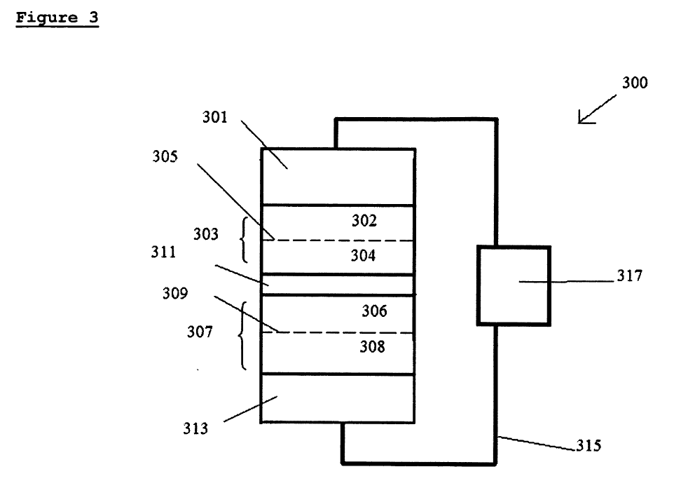

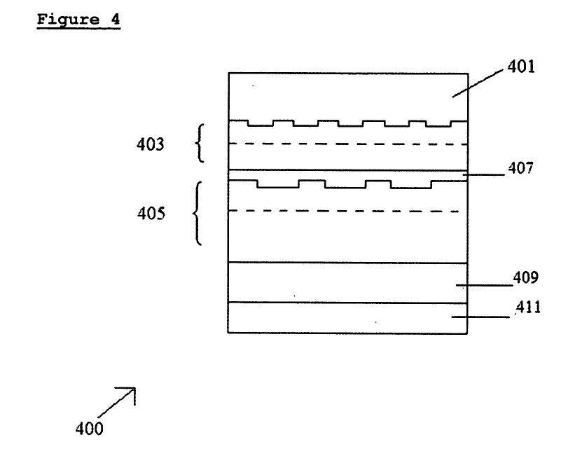

### DETAILED DESCRIPTION OF THE INVENTION

The embodiments of the present invention and its technical advantages are best understood by referring to FIG. 4. The present invention relates to a multi-junction solar cell, in which the sub-cells are all made of the same semiconductor material with its electronic structure modified by nanosized indentations or protrusions on the surface of each sub-cell.

Referring now to FIG. 4, which is a cross-sectional view of the multi-junction solar cell of the present invention. Shown is solar cell 400 comprising window layer 401, first or top sub-cell 403 and second or base sub-cell 405. Sub-cells 403 and 405 are connected via tunnel junction 407. Base sub-cell 405 lies on metal back contact 409 which is in turn supported by substrate 411.

Sub-cells 403 and 405 comprise the same semiconductor material, doped to form n and p junctions within each sub-cell. The sub-cells are therefore perfectly lattice matched, each having the identical lattice constant.

The surfaces of sub-cells 403 and 405 are modified by nanoscale indentations or protrusions. Methods for carrying this out are well known to those skilled in the art and include screen printing, as used for printing CD surfaces, electron beam lithography and other imprinting processes.

The depth of the indentations or protrusions is chosen so that the probability wave of an electron reflected from the bottom of the indent or top of the protrusion interferes destructively with the probability wave of an electron reflected from the surface. This results in a modification of the electronic structure of the semiconductor comprising sub-cells 403 and 405.

Further theory and details pertaining to the structure of these indentations or protrusions are disclosed in prior art.

In a particularly preferred embodiment of the present invention the dimensions of the nanoscale indentations or protrusions are chosen so as to create destructive de Broglie interference of electrons of energies close to the energy of the band gap in the semiconductor comprising sub-cells 403 and 405. In this embodiment of the invention, the depth of the indents or height of the protrusions is typically ≧λ/2 where λ is the de Broglie wavelength of an electron of energy close to the bandgap energy of the semiconductor. The width of the indents or protrusions is >>λ.

The presence of such indentations or protrusions on the surface of sub-cells 403 and 405 gives rise to modified bandgaps in sub-cells 403 and 405. The modification to the bandgap depends on the precise depth of the indentations or protrusions.

In a preferred embodiment of the present invention, the bandgaps of the sub-cells are modified so as to decrease as solar cell 400 is descended; that is top sub-cell 403 has a larger bandgap and base sub-cell 405 has a smaller bandgap. This is achieved by varying the depth of the indents or protrusions on the surface of sub-cells 403 and 405. The exact dimensions chosen depend on the value of λ, the wavelength of the electron to be eliminated. The greater the energy of the electron to be eliminated, the smaller its wavelength and therefore the smaller the depth of the indent required in order to create destructive interference. Therefore, in general terms, the height of the indents is decreased as solar cell 400 is descended, whilst the width of the indents is maintained, so as to decrease the size of the band gap.

In a preferred embodiment of the present invention the indents or protrusions are of a depth less than 10 nm and width less than 1 micrometre.

In order for current matching to be achieved, whereby equal photo-current is produced by each sub-cell, the thicknesses of the sub-cells must be varied to compensate for their differences in absorptivity. This can be seen in FIG. 4, where sub-cell 403, with the larger bandgap and therefore greater absorptivity is thinner than sub-cell 405, which has a smaller bandgap, therefore lower absorptivity and so is thicker.

In another possible embodiment of the present invention the dimensions of the nanoscale indentations or protrusions are such so as to create a forbidden quantum region immediately below the valence band in the semiconductor comprising sub-cells 403 and 405. The is achieved by finely controlling the dimensions of the indentations or protrusions so as to create destructive de Broglie interference of electrons having energies immediately below the valence band energy. Due to the destructive interference, quantum states in the energy range immediately below the valence band cannot be occupied leading to the induction of the equivalent of a band gap in this region.

Note that this embodiment of the present invention is in contrast to the previously described embodiment of the present invention in which the protrusions are designed in order to modify the size of the already present band-gap rather than create an additional band gap. Further theory and details pertaining to the structure of these indentations or protrusions are disclosed in prior art.

In this latter embodiment of the present invention, two band gaps are effectively present in the semiconductor comprising sub-cells 403 and 405—the intrinsic band gap that exists in the semiconductor material and an additional induced band gap due to the presence of surface nanoscale indentations or protrusions. The induced band gap allows the utilization of photons with a wider range of energies since photons of energy equal to the sum of the intrinsic and induced band gap can now be absorbed.

In a particularly preferred embodiment of the present invention, all layers comprise thin films. In this embodiment, solar cell 400 is assembled monolithically, starting with a thin film of metal deposited on substrate 411 forming metal back contact 409. This deposition can be carried out using a variety of methods, well known to those skilled in the art, including sputtering and physical vapor deposition. All other overlying films are deposited by methods known in the art including a combination of “ink-jet” printing the individual components followed by thermal annealing.

Solar photons enter solar cell 400 via window layer 401. These photons undergo absorption, transmission or reflection depending on the magnitude of their energies relative to that of the bandgap in top sub-cell 403. Photons with energies equal to or greater than the bandgap are absorbed by sub-cell 403 and converted to electricity through the process of electron-hole formation and subsequent separation.

Photons with energies less than the band-gap of sub-cell 403 are transmitted to sub-cell 405. Since sub-cell 405 has a smaller bandgap than top sub-cell 403 photons that could not be absorbed by sub-cell 403 due to their relatively small energies are now equal to or greater than the bandgap energy of intermediate sub-cell 405. These photons can therefore be absorbed and converted to electricity in sub-cell 405. Thus, illustrated solar cell 400 is configured to absorb sunlight in two incremental steps, with increasingly long wavelength, low frequency photons absorbed by each sub-cell.

The incremental process described may be continued with the addition of additional sub-cells that provide one or more additional steps for converting the received solar radiation.

Thus, in further possible embodiments of the present invention, solar cell 400 comprises three or more sub-cells, each sub-cell preferably fabricated to be lattice- and current-matched by using the same semiconductor material with a modified bandgap and controlled thickness.

To facilitate photocurrent flow between sub-cells 403 and 405, solar cell 400 includes low-resistivity tunnel junction 407 between the sub-cells.

In a preferred embodiment of the present invention tunnel junction 407 comprises highly doped GaAs. In another preferred embodiment of the present invention, tunnel junction 407 comprises a semiconductor with a lattice constant substantially equal to that of the semiconductor comprising the sub-cells.

In a preferred embodiment of the present invention top sub-cell 403 has a bandgap substantially equal to 1.75 eV. In a further preferred embodiment of the present invention base sub-cell 405 has a bandgap substantially equal to 1.25 eV.

In one possible embodiment of the present invention, wherein solar cell 400 comprises three sub-cells through the addition of a sub-cell below base sub-cell 405, the additional sub-cell has a band gap substantially equal to 1 eV.

In a preferred embodiment of the invention, sub-cells 403 and 405 comprise doped GaAs. In a further preferred embodiment of the invention, semiconductor silicon compounds are the comprising material. In a further possible embodiment of the present invention, sub-cells 403 and 405 comprise Copper Indium Gallium Diselenide (CIGS).

Although the description above contains many specificities, these should not be construed as limiting the scope of the present invention but as merely providing illustrations of some of the presently preferred embodiments of the invention. Thus the scope of the present invention should be determined by the appended claims and their legal equivalents, rather than by the examples given.

1. A multi-junction solar cell comprising
a) a substrate,
b) a metal layer, wherein said metal layer is disposed on said substrate,
c) a first sub-cell positioned adjacent to said metal layer wherein said first sub-cell comprises a semiconductor p/n junction and wherein the surface of said first sub-cell is characterised by a periodically repeating structure having one or more indents or protrusions of a depth≧λ/2 and width>>λ wherein λ is the de Broglie wavelength corresponding to an electron of a predetermined energy in said semiconductor,
d) a second sub-cell positioned adjacent to said first sub-cell, wherein said second sub-cell comprises a semiconductor p/n junction comprising the same semiconductor as said first sub-cell and wherein the surface of said second sub-cell is characterised by a periodically repeating structure having one or more indents or protrusions of a depth≧λ/2 and width>>λ wherein λ is the de Broglie wavelength of an electron of predetermined energy in said semiconductor and wherein said predetermined energy is not equal to said predetermined energy of said electron in said first sub-cell,
e) a tunnel junction layer interposed between said first sub-cell and said second sub-cell, whereby current flow between said sub-cells is facilitated,
f) a window layer positioned adjacent to said second sub-cell, whereby radiation enters said solar cell; and
g) electrical contacts attached to said solar cell to conduct current away from and into said solar cell.

2. The device of claim 1, wherein said first and second sub-cells each have a thickness, said thickness of each of said sub-cells being selected to optimize the solar to electrical energy conversion efficiency of said solar cell.

3. The device of claim 1 wherein said semiconductor p/n junctions of said first and second sub-cells comprise GaAs or CIGS.

4. The device of claim 1 wherein said substrate comprises a semiconductor.

5. The device of claim 4 wherein said semiconductor comprises the same semiconductor as comprises said semiconductor p/n junctions of said first and second sub-cells.

6. The device of claim 1 wherein said substrate comprises a polymer.

7. The device of claim 1 wherein said metal layer comprises Molybdenum or Copper.

8. The device of claim 1 wherein said periodically repeating structure comprises a means of altering the bandgaps of said semiconductor p/n junctions of said first and second sub-cells.

9. The device of claim 1 wherein said periodically repeating structure comprises a means of creating an induced band gap, wherein said induced band gap lies below the valence band in said semiconductor p/n junctions of said first and second sub-cells.

10. The device of claim 1 wherein said semiconductor p/n junction of said second sub-cell has a bandgap greater than that of said semiconductor p/n junction of said first sub-cell.

11. The device of claim 10 wherein said semiconductor p/n junction of said second sub-cell has a bandgap substantially equal to or greater than 1.75 eV.

12. The device of claim 10 wherein said semiconductor p/n junction of said first sub-cell has a bandgap substantially equal to 1.25 eV.

13. The device of claim 1 further including
a) an additional sub-cell positioned between said substrate and said first sub-cell, wherein said additional sub-cell comprises a semiconductor p/n junction comprising the same semiconductor as said first sub-cell and wherein the surface of said additional sub-cell is characterised in that it has a periodically repeating structure having one or more indents of nano-dimensions,
b) a tunnel junction layer interposed between said first sub-cell and said additional sub-cell.

14. The device of claim 13 wherein said semiconductor p/n junction of said additional sub-cell has a bandgap substantially equal to 1 eV.

15. The device of claim 13 wherein the bandgap of said semiconductor p/n junction of said additional sub-cell is smaller than that of said semiconductor p/n junction of said first sub-cell.

16. The device of claim 13 further including additional sub-cells, wherein said additional sub-cells are positioned adjacent to already present sub-cells, comprise the same semiconductor material as said already present sub-cells and are separated from said already present sub-cells by additional tunnel layers.

17. The device of claim 1 wherein said depth is less than 10 nm and said width is less than 1 micrometre.

18. The device of claim 1 in which said predetermined energy of said electron in said first sub-cell is less than said predetermined energy of said electron in said second sub-cell and accordingly wherein said depth of said indents or protrusions in first sub-cell is less than said depth of said indents or protrusions in said second sub-cell.

19. The device of claim 1 in which said width of said indents or protrusions in said first and second sub-cells are substantially equal.
